(19) United States
(12) Patent Application Publication
(10) Pub. No.: US 2007/0023168 A1
(43) Pub. Date: Feb. 1, 2007

(54) Apparatus for cooling electronic components

(75) Inventors: Markus Flesch, Kornwestheim (DE); Andreas Klenk, Ludwigsburg (DE); Thomas Siebrecht, Ludwigsburg (DE)

Correspondence Address: FOLEY AND LARDNER LLP;SUITE 500, 3000 K STREET NW, WASHINGTON, DC, 20007, US

(73) Assignee: BEHR INDUSTRY GmbH & CO. KG

(21) Appl. No.: 11/493,915

(22) Filed: Jul. 27, 2006

(30) Foreign Application Priority Data
Jul. 27, 2005 (DE) 10 2005 034 998.6

(51) Int. Cl. H05K 7/20

(52) U.S. Cl. 165/80.4; 165/170; 361/699

(57) ABSTRACT

An apparatus (1) for cooling electronic components (2, 3, 4) comprises laminated plate-like parts that form a flow duct through which a liquid coolant can flow. At least one plate-like frame element (8) having cutouts (9, 10, 11) is arranged between the plate-like parts, wherein the cutouts (9, 10, 11) form sections of a coolant flow duct for selectively cooling electronic components mounted on mounting areas on one or more surfaces of the apparatus.

### CROSS-REFERENCE TO RELATED PATENT APPLICATIONS

The right of foreign priority is claimed under 35 U.S.C. § 119(a) based on Federal Republic of Germany Application No. 10 2005 034 998.6, filed Jul. 27, 2005, the entire contents of which, including the specification, drawings, claims and abstract, are incorporated herein by reference.

### BACKGROUND OF THE INVENTION

The invention relates to an apparatus for cooling electronic components, of the type comprising plate-like parts which form a flow duct through which a liquid coolant can flow.

A known cooling device of this type is disclosed in commonly assigned DE 41 31 739 A1, for use in cooling electrical components. This device essentially comprises two plate-like parts, a base plate and a cover plate, which enclose a cavity through which a liquid coolant can flow. In order to improve the heat transfer, a turbulence insert is arranged in the cavity that acts as a flow duct. The electrical components are arranged on the base plate in a thermally conductive manner and dissipate their heat loss to the coolant via the base plate. Production of the known cooling device entails relatively high costs, since the cavity is produced by machining (milling) the base plate and is sealed by means of a cover plate which is screwed to the base plate. In addition, depending on the arrangement and respective power loss of the electronic components, a non-uniform introduction of heat may result for the base plate, which may result in different temperatures (non-uniform temperature distribution) and also in so-called hot spots. It is not possible to effectively cool the electronic components under these circumstances.

DE 199 11 205 A1 discloses a cooling apparatus for electronic components, the apparatus having two plate-like parts, a metal plate and a plastic box, which form a flow duct that runs in the form of a U. To this end, the plastic box has a separating web which subdivides the entire cavity between the two plates into two subspaces with a deflection element. Although this design achieves improved cooling, the same disadvantages also result in this case regarding the production costs and localized overheating when the electronic components introduce heat non-uniformly.

### SUMMARY OF THE INVENTION

It is therefore one object of the present invention to provide an improved apparatus for cooling electronic components, in particular a more efficient apparatus and one with reduced production costs and reduced installation space.

Another object of the invention resides in the provision of a method for producing the improved cooling apparatus according to the invention.

In accordance with one aspect of the present invention, there is provided an apparatus for cooling electronic components, comprising: first and second plate-like parts that are in a stacked configuration to define a heat exchanger body having a top surface formed by the first plate-like part and a bottom surface formed by the second plate-like part; at least one plate-like frame element having at least one cutout arranged in the stacked configuration between the plate-like parts, wherein the at least one cutout defines a flow duct through which a liquid coolant can flow; and a mounting area for at least one electronic component located on at least one of the top surface and the bottom surface.

In accordance with another aspect of the invention, there is provided a method for producing an apparatus for cooling electronic components, comprising: stacking first and second plate-like parts in a stacked configuration having a top surface formed by the first plate-like part and a bottom surface formed by the second plate-like part, wherein a mounting area for at least one electronic component is located on at least one of the top surface and the bottom surface; positioning at least one plate-like frame element having at least one cutout in the stacked configuration between the plate-like parts, wherein the at least one cutout defines a flow duct through which a liquid coolant can flow; and bonding the stacked configuration together.

Further objects, features and advantages of the present invention will become apparent from the detailed description of preferred embodiments that follows, when considered together with the accompanying figures of drawing.

### BRIEF DESCRIPTION OF THE DRAWINGS

In the drawings:

FIG. 1 is a perspective view showing a cooling apparatus according to one embodiment of the invention, in the form of a cooling plate bearing electronic components;

FIG. 2 is a perspective view showing the cooling plate according to FIG. 1 with the cover plate removed;

FIG. 3 is an exploded perspective view showing an exploded illustration of one embodiment of the cooling plate according to the invention before it is assembled and

FIG. 4 is an exploded perspective view showing an exploded illustration of another embodiment of the cooling plate according to the invention before it is assembled.

### DETAILED DESCRIPTION OF THE PREFERRED EMBODIMENTS

The invention provides for at least one plate-like frame element having cutouts arranged between the plate-like parts, the cutouts forming sections of a flow duct. The cutouts are thus connected to one another on the coolant side, it being possible for the cutouts to be connected in series and/or in parallel with one another. In principle, the cutouts have any desired shape and are matched, in terms of shape and arrangement, to the electronic components that are arranged on the cooling apparatus. Turbulence inserts that are positioned through the cutouts and improve the heat transfer to the coolant can optionally and advantageously be arranged in the cutouts. The plate-like frame element and the plate-like parts are preferably connected to one another by means of brazing or soldering, whereby plate-like carriers for brazing material are preferably used for this purpose. The advantageous feature of this design is the simple structure which is achieved by stacking and brazing/soldering plate-like parts. There is thus no need for any screwed joint and/or mechanical seals between the plates.

According to one particularly preferred embodiment of the invention, the cutouts are produced in the plate-like frame element by laser cutting or water jet cutting. This has the advantage that, on the one hand, any desired contours can be produced for the cutouts, i.e., the flow ducts, and, on the other hand, clean (non-cutting) and cost-effective manufacture is achieved. The inventive frame element can be produced in any desired wall thickness, which also corresponds to the height of the turbulence inserts, which is most preferably made from a cost-effective semi-finished material. It is also possible to use a plurality of identical frame elements which are stacked on top of one another in order to achieve a greater flow duct height.

According to another preferred embodiment of the invention, the frame element has next to it an intermediate element having one or more recesses that are used as distributor or collecting ducts for the flow ducts in the frame element. This intermediate plate makes it possible to improve the inflow and outflow of the coolant and to keep the flow velocity of the coolant low, to avoid excessively high flow velocities. The intermediate element is connected to the frame element and to the plate-like parts by a material joint, preferably by means of brazing/soldering. The cutouts for the distributor and/or collecting ducts may preferably also be produced by means of laser cutting and/or water jet cutting.

According to another preferred aspect of the invention, in addition to the first frame element, a second frame element having corresponding cutouts is provided, thus creating additional flow ducts for the coolant and thus providing additional cooling capacity, e.g., on both sides of the stacked configuration.

In another preferred embodiment of the invention, both sides (top side and underside) of the cooling apparatus may be in the form of cooling areas and may be fitted with the electronic components. The advantage of increased cooling capacity in conjunction with a small installation space is thus achieved.

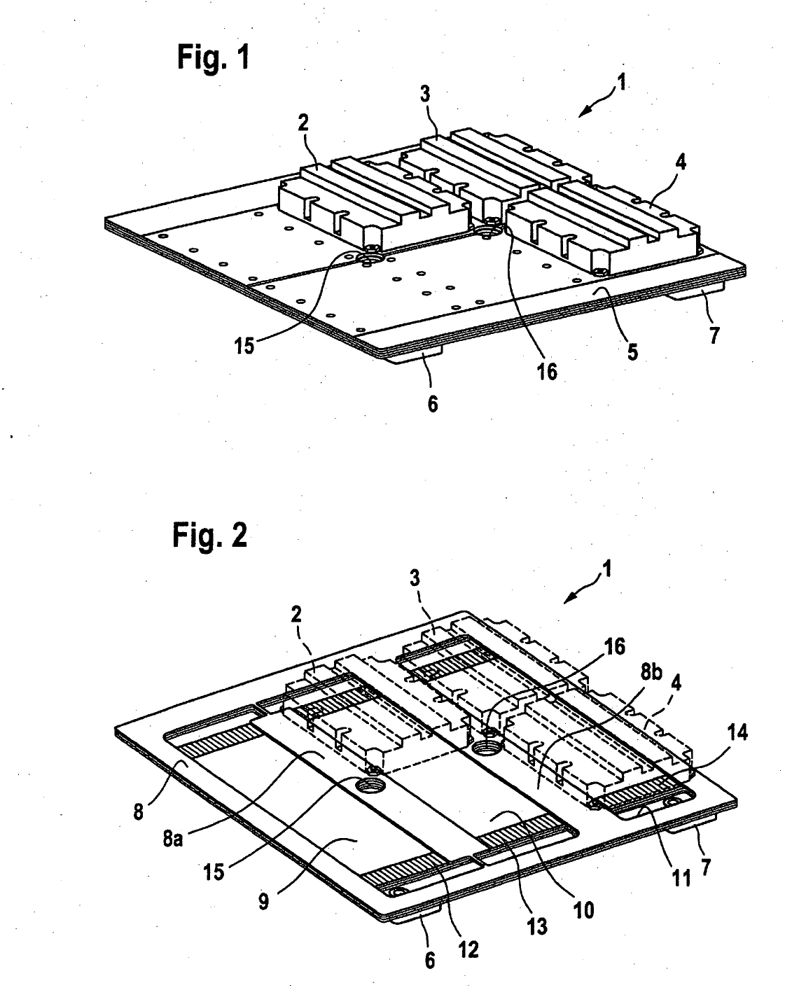

Turning now to the drawings, FIG. 1 shows a cooling apparatus according to one embodiment of the invention for electronic components, comprising a cooling plate 1 on which individual electronic components (which are to be cooled) in the form, e.g., of power semiconductors 2, 3, 4 are arranged. The cooling plate 1 is constructed from a plurality of plates in the manner of a laminate or sandwich, the uppermost plate being in the form of a cover plate 5 having a cooling area to which one or more electronic components 2, 3, 4 are fastened in a thermally conductive manner. Arranged on the underside of the cooling plate 1 are two coolant connections 6, 7 which are used to supply and discharge a fluid, preferably liquid coolant, for example, a water/glycol mixture.

FIG. 2 shows the cooling plate 1 with the cover plate 5 removed (and the electronic components being shown by dashed lines), with the result that a plate-like frame element 8 having three approximately rectangular cutouts 9, 10, 11 can be seen. The cutouts 9, 10, 11 are used as flow ducts for the liquid coolant and preferably accommodate turbulence inserts 12, 13, 14 in them (which is only partially illustrated for the sake of simplicity in FIG. 2). The cutouts 9, 10, 11 are at least partially matched, in terms of their arrangement and shape, to the power semiconductors 2, 3, 4, i.e., the liquid coolant preferentially flows past the underside of the power semiconductors 2, 3, 4 and can thus more efficiently and directly dissipate the heat loss absorbed. The coolant can flow through the cutouts or flow ducts in a parallel manner and/or in series. For example, the coolant that enters the coolant connection 6 can flow through the first two flow duct sections 9, 10 in a parallel manner, while the entire quantity of coolant which is discharged by the coolant connection 7 is subsequently applied to the third flow duct section 11.

Between the recesses 9, 10, 11, the frame element 8 has webs 8a, 8b in which positioning openings 15, 16 are arranged. The positioning openings, as also shown in FIG. 1, extend through the entire cooling plate 1. When assembling the cooling plate 1, the positioning openings 15, 16 are used to position the individual plate-like parts and thus preferably constitute an assembly aid.

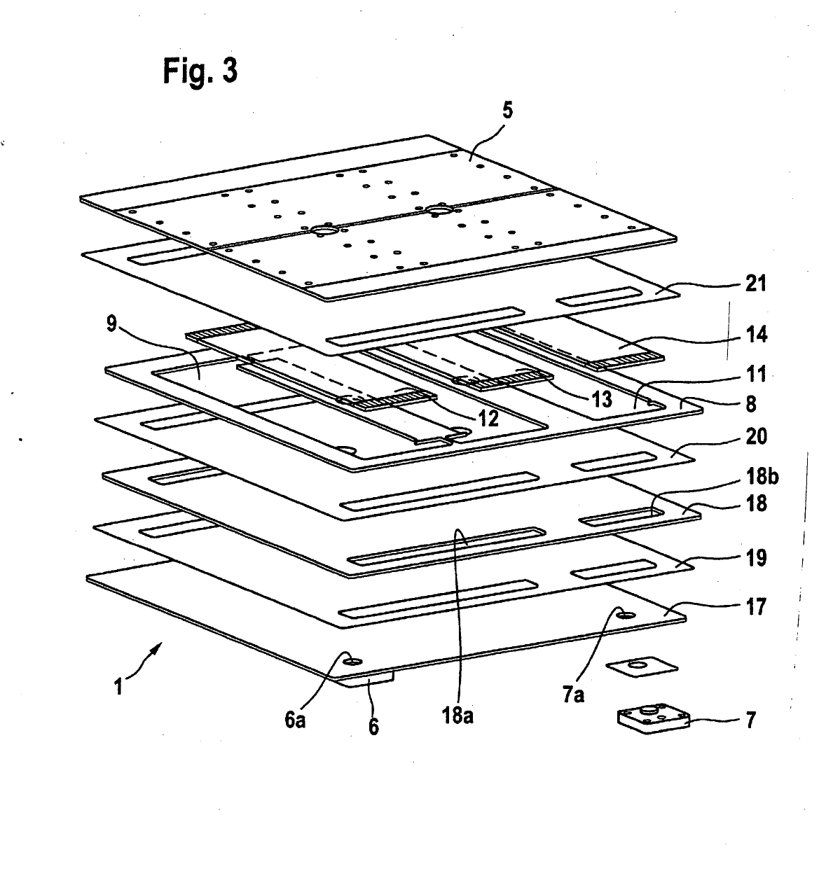

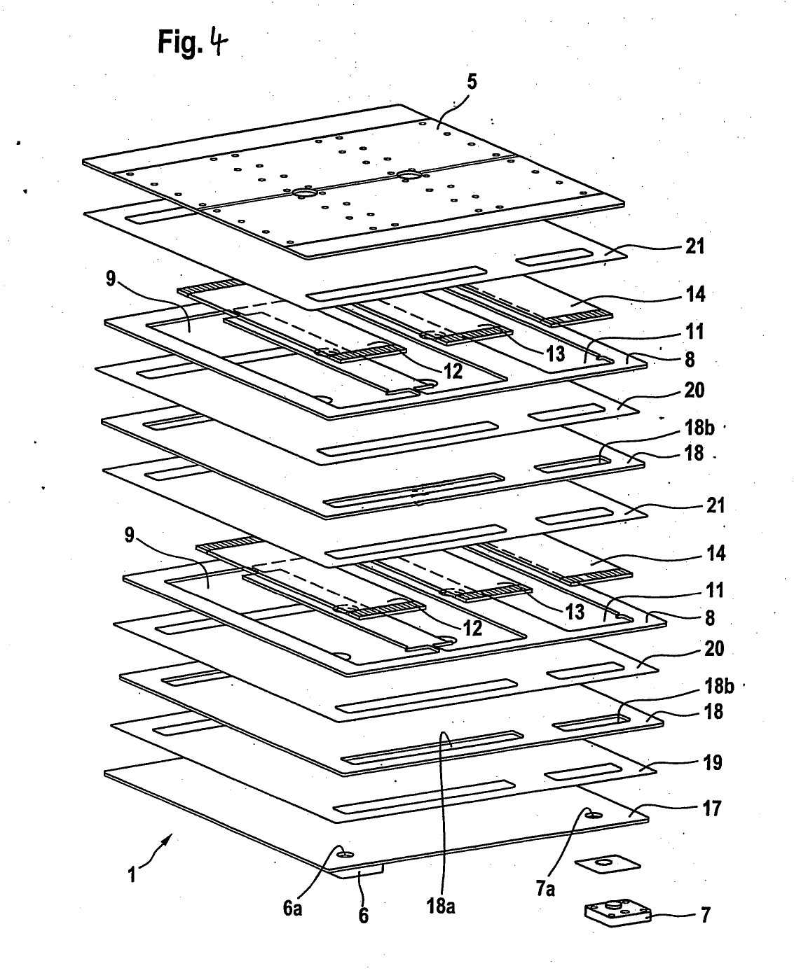

FIG. 3 shows an exploded illustration of the cooling plate 1 according to FIGS. 1 and 2, i.e., with its individual parts before they are assembled. The same reference numerals are used for corresponding parts. The cooling plate 1 is constructed from various plate-like elements in the manner of a laminate or sandwich, with the cover plate 5 forming the uppermost plate element and a base plate 17 forming the lowermost plate element. The plate-like frame element 8 and a plate-like intermediate element 18 are arranged between the cover plate 5 and the base plate 17. Plate-like braze carriers 19, 20, 21, which preferably comprise a carrier sheet which has been braze-coated on both sides, are respectively arranged between the base plate 17, the intermediate element 18, the frame element 8 and the cover plate 5. The coolant connections 6, 7 are fastened to the base plate 17, which has an entry bore 6a and an exit bore 7a. The turbulence inserts 12, 13, 14 are inserted into the corresponding cutouts 9, 10, 11 of the frame element 8. The plate-like elements 5, 8, 18, 17 are preferably produced from an aluminum alloy and are brazed/soldered together with the turbulence inserts 12, 13, 14, using the braze sheets or carriers 19, 20, 21 in a brazing oven (not illustrated), preferably without a flux. After brazing has been completed, a compact cooling plate 1, as illustrated in FIGS. 1 and 2, is produced.

The plate-like intermediate element 18 has two cutouts 18a, 18b, as well as further corresponding or similar cutouts on the opposite side (which cannot be seen in the drawing) that are used as collecting and distributor ducts for the coolant. The coolant preferably flows through the cooling plate 1 as follows. The liquid coolant enters via the coolant connection 6 and passes, via the bore 6a in the base plate 17, into the distribution cutout 18a, from which it enters the two flow duct sections 9, 10 and flows through the latter in a parallel manner. The coolant flow is then combined (which cannot be seen in the drawing) and is supplied to the third flow duct section 11. The coolant enters the collecting cutout 18b of the intermediate element 18 from the cutout 11 of the frame element 8 and then passes into the coolant exit 7 via the exit bore 7a in the base plate 17. Differing from the exemplary embodiment illustrated and described, other flow patterns through the cooling plate 1, in particular the frame element 8, are possible. For example, the coolant can flow through all three sections in succession or in a parallel manner. In addition, the shape and number of the sections may be varied and thus adapted to the respective pattern and/or capacity of electrical components that are to be carried by the cooling apparatus.

FIG. 4 shows an exploded illustration, similar to that in FIG. 3, of the cooling plate 1 according to another exemplary embodiment of the invention, i.e., with its individual parts shown before they are assembled. The same reference numerals are used for corresponding parts shown in the other figures, and the detailed discussion of the common elements will not be repeated here. According to this embodiment, a further plate-like frame element 8 is provided, i.e., in addition to the frame element 8 illustrated in FIG. 3, and corresponding layers comprised of intermediate plate 18 and plate-like braze carriers 19, 20, 21 can be incorporated, as illustrated. This makes it possible to create additional cooling ducts and to use both termination plates, namely, the upper plate 5 and the lower plate 17, as a cooling area and to fit them with electronic components. Base plate 17 can therefore be of the same or different configuration as cover plate 5. This provides increased cooling capacity in a small installation space. Other arrangements of layers are also possible according to this embodiment in which multiple frame elements 8 are included, e.g., an arrangement like that shown in FIG. 3 in which a mirror image arrangement of the plates stacked on top of base plate 17 are stacked and bonded in the same manner as the stack shown in FIG. 3 on top of base plate 17. The preferred manner of construction and bonding for the embodiment shown in FIG. 4 is, in principle, the same as described above in connection with FIG. 3. The additional frame element can be of the same or different configuration as frame element 8. The frame elements can be of any desired thickness, and one or more frame elements can be stacked on top of one another to modify the depth of the recesses formed by the cut-outs.

The foregoing description of preferred embodiments of the invention has been presented for purposes of illustration and description only. It is not intended to be exhaustive or to limit the invention to the precise form disclosed, and modifications and variations are possible and/or would be apparent in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto and that the claims encompass all embodiments of the invention, including the disclosed embodiments and their equivalents.

What is claimed is:

1. An apparatus for cooling electronic components, comprising:
first and second plate-like parts that are in a stacked configuration to define a heat exchanger body having a top surface formed by the first plate-like part and a bottom surface formed by the second plate-like part;
at least one plate-like frame element having at least one cutout arranged in the stacked configuration between the plate-like parts, wherein the at least one cutout defines a flow duct through which a liquid coolant can flow; and
a mounting area for at least one electronic component located on at least one of the top surface and the bottom surface.

2. An apparatus according to claim 1, further comprising a device for generating turbulence arranged inside at least one cutout.

3. An apparatus according to claim 1, comprising a plurality of cutouts, wherein each cutout comprises an approximately rectangular shape and the cutouts are connected to one another for fluid flow.

4. An apparatus according to claim 2, wherein the frame element has a wall thickness corresponding to the height of the turbulence-generating device.

5. An apparatus according to claim 2, wherein at least one of the frame element and the turbulence-generating device is/are connected to the plate-like parts by a material joint.

6. An apparatus according to claim 5, wherein the material joint comprises a brazed joint.

7. An apparatus according to claim 6, further comprising plate-like brazing sheets arranged between the frame element and the plate-like parts.

8. An apparatus according to claim 1, further comprising coolant connections on one of the plate-like parts, to constitute a base plate.

9. An apparatus according to claim 8, further comprising in the stacked configuration at least one plate-like intermediate element having a distributor and/or collecting cutout therein that fluidly communicates with the at least one cutout of the frame element, arranged between the frame element and the base plate.

10. An apparatus according to claim 9, wherein at least one of the cutouts and/or the distributor and collecting cutouts is produced by laser cutting and/or water jet cutting.

11. An apparatus according to claim 1, further comprising a second frame element for forming a second flow duct.

12. An apparatus according to claim 11, wherein both the top surface and the bottom surface the plate-like components include a mounting area for mounting at last one electronic component.

13. A method for producing an apparatus for cooling electronic components, comprising:
stacking first and second plate-like parts in a stacked configuration to define a heat exchanger body having a top surface formed by the first plate-like part and a bottom surface formed by the second plate-like part, wherein a mounting area for at least one electronic component is located on at least one of the top surface and the bottom surface;
positioning at least one plate-like frame element having at least one cutout in the stacked configuration between the plate-like parts, wherein the at least one cutout defines a flow duct through which a liquid coolant can flow; and
bonding the stacked configuration together.
